(19) United States
(12) Patent Application Publication
(10) Pub. No.: US 2022/0252976 A1
(43) Pub. Date: Aug. 11, 2022

(54) PHOTORESIST COMPOSITIONS AND METHODS OF MANUFACTURING INTEGRATED CIRCUIT DEVICE USING THE SAME

(71) Applicant: Samsung Electronics Co., Ltd., Suwon-si (KR)

(72) Inventors: Hyun-Ji SONG, Anyang-si (KR); Hyunwoo KIM, Seongnam-si (KR); Sukkoo HONG, Suwon-si (KR)

(21) Appl. No.: 17/567,956

(22) Filed: Jan. 4, 2022

(30) Foreign Application Priority Data
Feb. 10, 2021 (KR) 10-2021-0019368

(51) Int. Cl. G03F 7/004

(52) U.S. Cl. CPC G03F 7/0044; G03F 7/0045

(57) ABSTRACT

Photoresist compositions may include a metal structure, a radical quencher including a phenolic compound, a photobase generator, and a solvent. To manufacture an integrated circuit (IC) device, a photoresist film is formed on a lower film using the photoresist composition. A first area, which is a portion of the photoresist film, is exposed to form a metal network from the metal structure in the first area of the photoresist film, a base is generated from the photobase generator in the first area of the photoresist film, and the radical quencher is deactivated using the base in the first area of the photoresist film. The photoresist film is developed to form a photoresist pattern including the first area. The lower film is processed using the photoresist pattern.

### CROSS-REFERENCE TO RELATED APPLICATION

This application is based on and claims priority under 35 U.S.C. § 119 to Korean Patent Application No. 10-2021-0019368, filed on Feb. 10, 2021, in the Korean Intellectual Property Office, the disclosure of which is incorporated by reference herein in its entirety.

### BACKGROUND

The inventive concept relates to a photoresist composition and a method of manufacturing an integrated circuit (IC) device using the same, and more particularly, to a photoresist composition containing a metal and a method of manufacturing an IC device using the photoresist composition.

In recent years, the downscaling of semiconductor devices has rapidly progressed due to the development of electronic technology. Thus, a photolithography process, which is advantageous in forming fine patterns, may be required. In particular, it is necessary to develop a photoresist composition which may improve a sensitivity and a critical dimension (CD) uniformity while obtaining excellent etching resistance and resolution in a photolithography process for manufacturing an IC device.

### SUMMARY

The inventive concept provides photoresist compositions that provides excellent etching resistance, high resolution, uniform wafer-to-wafer and/or in-wafer critical dimension (CD) distributions, and improved sensitivity during a photolithography process for manufacturing an integrated circuit (IC) device.

The inventive concept provides methods of manufacturing an IC device, which may reduce or prevent the degradation of a CD distribution due to the diffusion of radicals from an exposed area of a photoresist film into a non-exposed area thereof at a boundary between the exposed area and the non-exposed area of the photoresist film during a photolithography process, and may improve the dimensional accuracy of a pattern to be formed.

According to some embodiments of the inventive concept, there are provided photoresist compositions including a metal structure including an organic metal compound, an organic metal nanoparticle, or an organic metal cluster, a radical quencher including a phenolic compound, a photobase generator, and a solvent.

According to some embodiments of the inventive concept, there are provided photoresist compositions including (i) a metal structure including a metal core including at least one metal atom and (ii) at least one organic ligand associated with the metal core, a radical quencher including a phenolic compound, a photobase generator including a material capable of generating a base having an acid dissociation constant (pKa) of at least about 10 in water, and a solvent.

According to some embodiments of the inventive concept, there are provided methods of manufacturing an IC device. The method may include forming a photoresist film on a lower film using a photoresist composition including a metal structure including an organic metal compound, organic metal nanoparticles, or an organic metal cluster, a radical quencher including a phenolic compound, a photobase generator, and a solvent. A first area of the photoresist film, which is a portion of the photoresist film, may be exposed to light to form a metal network from the metal structure in a first area of the photoresist film. A base is generated from the photobase generator in the first area of the photoresist film. The radical quencher is deactivated using the base in the first area of the photoresist film. The photoresist film is developed to form a photoresist pattern including the first area. The lower film is processed using the photoresist pattern.

According to some embodiments of the inventive concept, photoresist compositions are provided. The photoresist compositions may include: a metal structure including a metal atom and an organic ligand bound to the metal atom; a radical quencher including a phenolic compound; and a photobase generator.

### BRIEF DESCRIPTION OF THE DRAWINGS

Embodiments of the inventive concept will be more clearly understood from the following detailed description taken in conjunction with the accompanying drawings in which:

FIG. 1 is a flowchart of a method of manufacturing an integrated circuit (IC) device, according to some embodiments of the inventive concept; and

FIGS. 2A to 2E are cross-sectional views illustrating a method of manufacturing an IC device, according to embodiments of the inventive concept.

### DETAILED DESCRIPTION

Hereinafter, some embodiments of the inventive concept will be described in detail with reference to the accompanying drawings. The same reference numerals are used to denote the same elements in the drawings, and repeated descriptions thereof may be omitted.

As used herein, the abbreviation “Me” refers to a methyl group, “Et” refers to an ethyl group, “Pr” refers to a propyl group, “iPr” refers to an isopropyl group, “Bu” refers to a butyl group, and “tBu” refers to a tert-butyl group (1,1-dimethylethyl group).

A photoresist composition according to some embodiments may include a metal structure, a radical quencher including a phenolic compound, a photobase generator, and a solvent.

The metal structure may include a metal compound (e.g., an organic metal compound), metal nanoparticles (e.g., organic metal nanoparticles), or a metal cluster (e.g., an organic metal cluster). In example embodiments, the metal structure may include a metal core including at least one metal element (e.g., atom) and at least one organic ligand surrounding (e.g., associated with) the metal core. The at least one organic ligand may be associated with (e.g., bound to) the metal core. In the metal structure, the organic ligand may be bound to the metal core via an ionic bond, a covalent bond, a metal bond, or a van der Waals bond.

The metal core may include at least one metal element. The at least one metal element may have the form of a metal atom, a metal ion, a metal compound, a metal alloy, or a combination thereof. The metal compound may include a metal oxide, a metal nitride, a metal oxynitride, a metal silicide, a metal carbide, or a combination thereof. In example embodiments, the metal core may include a metal element selected from tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (V), chromium (Cr), cobalt (Co), nickel (Ni), copper (Cu), gallium (Ga), manganese (Mn), copper (Cu), strontium (Sr), tungsten (W), cadmium (Cd), molybdenum (Mo), tantalum (Ta), niobium (Nb), cesium (Cs), barium (Ba), lanthanum (La), cerium (Ce), iron (Fe), and any combination thereof. The inventive concept is not limited the metals listed herein.

In example embodiments, the at least one metal element may be included in the form of metal oxide nanoparticles in the metal core. The metal oxide nanoparticles may include titanium dioxide, zinc oxide, zirconium dioxide, nickel oxide, cobalt oxide, manganese oxide, copper oxide, iron oxide, strontium titanate, tungsten oxide, vanadium oxide, chromium oxide, tin oxide, hafnium oxide, indium oxide, cadmium oxide, molybdenum oxide, tantalum oxide, niobium oxide, aluminum oxide, or a combination thereof. The metal oxide nanoparticles may have a particle size of about 1 nm to about 10 nm, for example, a particle size of about 2 nm to about 5 nm, without being limited thereto.

In example embodiments, the organic ligand may include a C1 to C30 linear alkyl group, a C1 to C30 branched alkyl group, a C2 to C30 alkenyl group, a C2 to C30 alkynyl group, a C3 to C30 cycloalkyl group, a C6 to C30 aryl group, a C3 to C30 allyl group, a C1 to C30 alkoxy group, a C6 to C30 aryloxy group, or a combination thereof. The organic ligand may include a hydrocarbyl group, which is substituted with at least one heteroatom functional group including an oxygen atom, a nitrogen atom, a halogen element, cyano, thio, silyl, ether, carbonyl, ester, nitro, amino, or a combination thereof. The halogen element may be fluorine (F), chlorine (C1), bromine (Br), or iodine (I). Throughout the specification, a functional group (e.g., an alkyl group, an aryl group, and alkoxy group) include both a substituted functional group and an unsubstituted functional group unless specified otherwise.

For example, the organic ligand may include methyl, ethyl, propyl, butyl, isopropyl, tertiary butyl, tertiary amyl, secondary butyl, cyclopropyl, cyclobutyl, cyclopentyl, or cyclohexyl. The metal structure may include a plurality of organic ligands, and two of the plurality of organic ligands may form one cyclic alkyl moiety. The cyclic alkyl moiety may include 1-adamantyl or 2-adamantyl.

In example embodiments, the organic ligand may include an aromatic ring, a hetero aromatic ring, or a combination thereof.

In example embodiments, the organic ligand may include at least one selected from the following structural units. In the following structures, “*” denotes a bonding site.

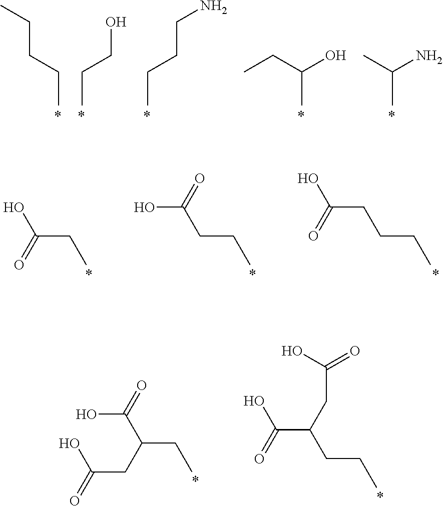

In other example embodiments, the organic ligand may include at least one selected from the following structural units. In the following structures, “*” denotes a bonding site.

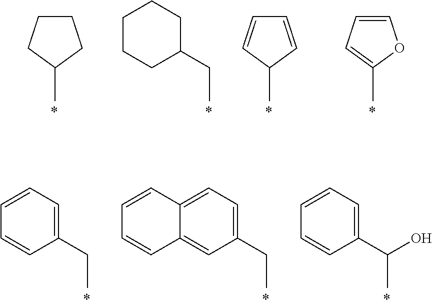

In yet other example embodiments, the organic ligand may include at least one selected from the following structural units.

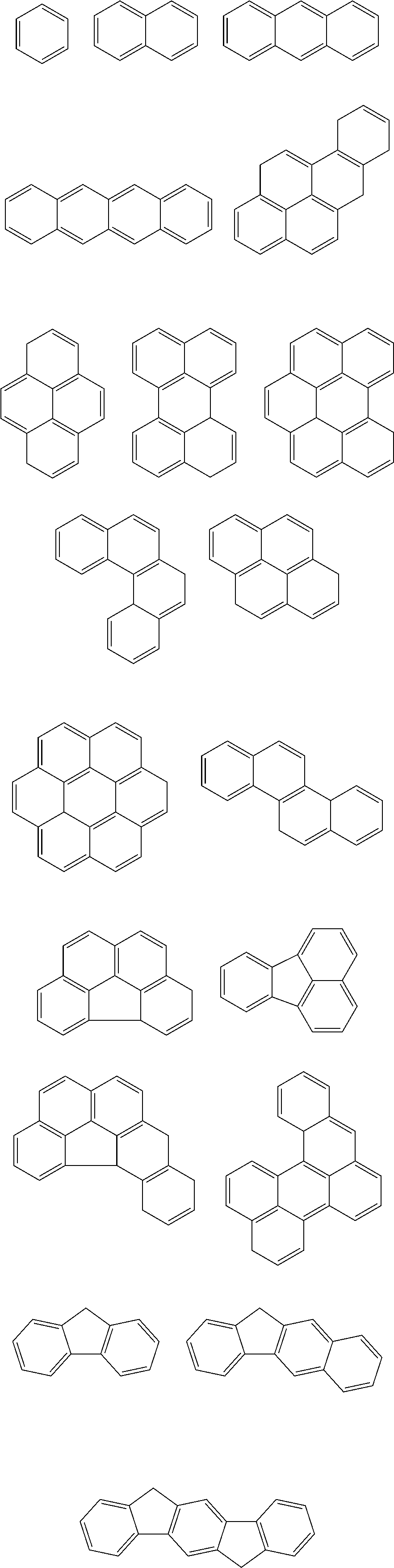

In example embodiments, the metal structure may include (tBu)Sn(NEt₂)₂(OtBu), (tBu)Sn(NEt₂)(NH₂)(OtBu), (tBu)Sn(NEt₂)(OtBu)₂, (Me)Sn(NEt₂)(OtBu)₂, (Me)Sn(NEt₂)₂(OtBu), (tBu)₂Sn(NEt₂)(OtBu), (Me)₂Sn(NEt₂)(OtBu), (Me)(tBu)Sn(NEt₂)₂, (Me)(tBu) Sn(NEt₂)(OtBu), (iPr)(tBu)Sn(NMe₂)(OtBu), or a combination thereof.

In other example embodiments, the metal structure may include at least one compound selected from the following Formulas 1 to 7:

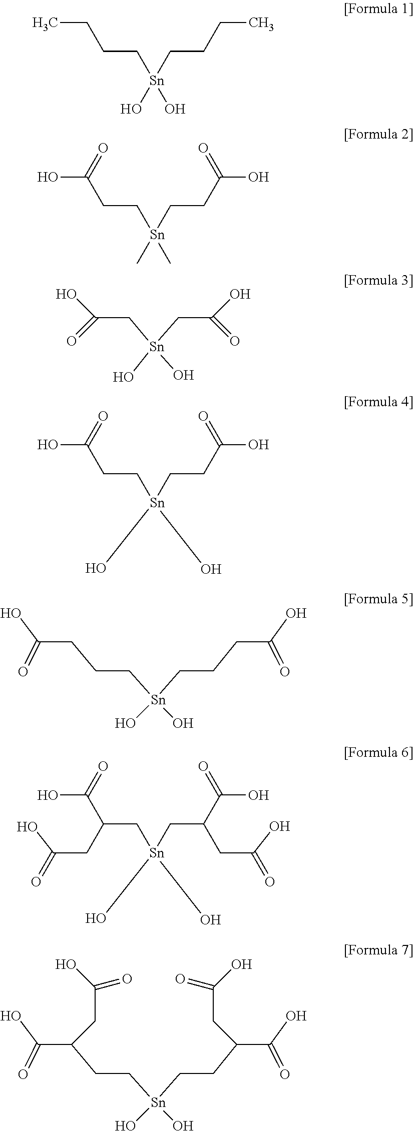

In yet other example embodiments, the metal structure may include a cage compound represented by [(SnBu)₁₂O₁₄(OH)₆]R₂. Herein, R may denote an anion component, which may be hydroxide, acetate, malonate, or tosylate, which is bonded to a tin (Sn) atom.

In the photoresist composition according to some embodiments, the metal structure may be contained at a content of about 0.1% to about 90% by weight, based on the total weight of the photoresist composition. When a content of the metal structure is excessively low or high in the photoresist composition, the storage stability of the photoresist composition may be degraded, and the ability to form a photoresist film using the photoresist composition may be reduced.

In the photoresist composition according to some embodiments, the radical quencher may be represented by the following General formula 1.

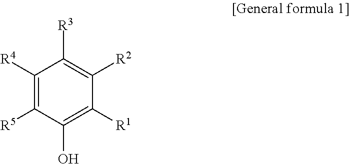

wherein each of R¹ to R⁵ is independently a hydrogen atom, a hydroxyl group, a C1 to C30 linear alkyl group, a C1 to C30 branched alkyl group, a C2 to C30 alkenyl group, a C2 to C30 alkynyl group, a C3 to C30 cycloalkyl group, a C6 to C30 aryl group, a C3 to C30 allyl group, a C1 to C30 alkoxy group, a C6 to C30 aryloxy group, a C7 to C20 arylalkyl group, a C3 to C20 heteroaryl group, a C7 to C30 heteroarylalkyl group, —ROR′ (where R is a C1 to C20 substituted or unsubstituted alkylene group, and R′ is a hydrogen atom or a C1 to C20 alkyl group), —RC(═O)X (where R is a C1 to C20 substituted or unsubstituted alkylene group, and X is a halogen atom), —C(═O)OR′ (where R′ is a hydrogen atom or a C1 to C20 alkyl group), —OC(═O)R′ (where R′ is a hydrogen atom or a C1 to C20 alkyl group), —CN, —OC(═O)NR″R′ (where each of R″ and R′ is independently a hydrogen atom or a C1 to C20 alkyl group), —S(═O)R′ (where R′ is a hydrogen atom or a C1 to C20 alkyl group), and —S(═O)₂R′ (where R′ is a hydrogen atom or a C1 to C20 alkyl group), and two adjacent groups selected from R¹ to R⁵ may be linked to each other to form a ring.

In example embodiments, the radical quencher may include an acidic material having an acid dissociation constant (pKa) of about 3 to about 13 in water. In some embodiment, the radical quencher may have an acid dissociation constant (pKa) of about 3 to about 13 in water.

In example embodiments, the radical quencher may include a phenol compound having a symmetric steric hindrance. In other example embodiments, the radical quencher may include a phenol compound having an asymmetric steric hindrance. As used herein, the expression “phenol compound having a symmetric steric hindrance” refers to a phenol compound having a symmetric chemical structure. As used herein, the expression “phenol compound having an asymmetric steric hindrance” refers to a phenol compound without a symmetric chemical structure.

The radical quencher including the phenol compound having the symmetric steric hindrance may include a symmetric monophenol compound or a symmetric polyphenol compound. The symmetric polyphenol compound may include a symmetric diphenol compound, a symmetric triphenol compound, and/or a symmetric heterocyclic polyphenol compound, without being limited thereto. For example, the phenol compound having the symmetric steric hindrance may include 2,6-di-tert-butyl-4-methylphenol, pentaerythritol tetrakis (3-(3,5-di-tert-butyl-4-hydroxyphenyl)propionate), octadecyl 3-(3,5-di-tert-butyl-4-hydroxyphenyl)propionate, 2-{3-[3,5-bis-(1,1-dimethylethyl)-4-hydroxyphenyl]-1-oxopropyl}-hydrazide), N,N′-hexane-1,6-diylbis[3-(3,5-di-tert-butyl)-4-hydroxyphenylpropionamide], 1,3,5-trimethyl-2,4,6-tris(3,5-di-tert-butyl-4-hydroxybenzyl)benzene, or a combination thereof, without being limited thereto

The radical quencher including the phenol compound having the asymmetric steric hindrance may include an asymmetric monophenol compound or an asymmetric polyphenol compound. The asymmetric polyphenol compound may include an asymmetric diphenol compound, an asymmetric triphenol compound, and/or an asymmetric N-containing heterocyclic polyphenol compound, without being limited thereto For example, phenol compound having an asymmetric steric hindrance may include ethylenebis (oxyethylene) bis-(3-(5-tert-butyl-4-hydroxy-m-tolyl)-propionate, without being limited thereto

In example embodiments, the radical quencher may include a symmetric or asymmetric monophenol compound. For example, the radical quencher including monophenol may be selected from phenol, ortho-cresol, meta-cresol, para-cresol, ortho-chlorophenol, meta-chlorophenol, para-chlorophenol, 2-hydroxybenzoic acid, 3-hydroxybenzoic acid, 4-hydroxybenzoic acid, 4-vinylphenol, 4-ethylphenol, 4-isopropylphenol, 4-isobutylphenol, and para-coumaric acid, but is not limited to the examples described above.

In other example embodiments, the radical quencher may include a symmetric or asymmetric polyphenol compound. For example, the radical quencher including polyphenol may be selected from 1,3-dihydroxybenzene (resorcinol), benzene-1,3,5-triol (phloroglucinol), 2,2′,4,4′-tetrahydroxydiphenyl sulfide, and 2,2′,4,4′-tetrahydroxybenzophenone, but the inventive concept is not limited to the examples.

In other example embodiments, the radical quencher may include at least one selected from the following phenol compounds. However, the inventive concept is not limited thereto.

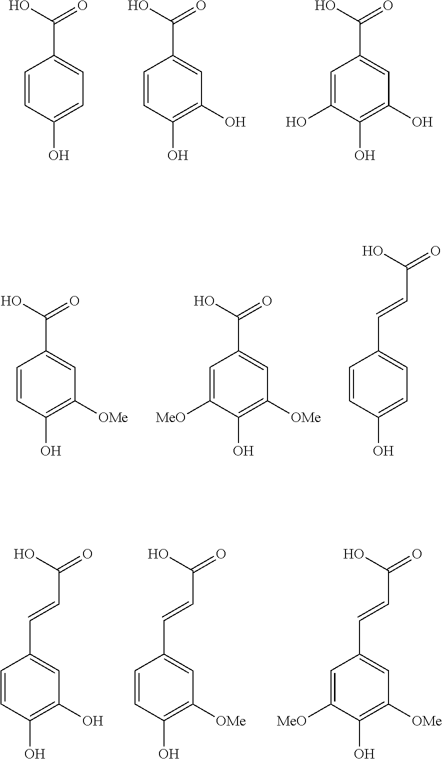

In other example embodiments, the radical quencher may include a flavonoid compound, which is a derivative of a phenolic compound. For example, the radical quencher may include at least one selected from the following flavonoid compounds. However, the inventive concept is not limited thereto.

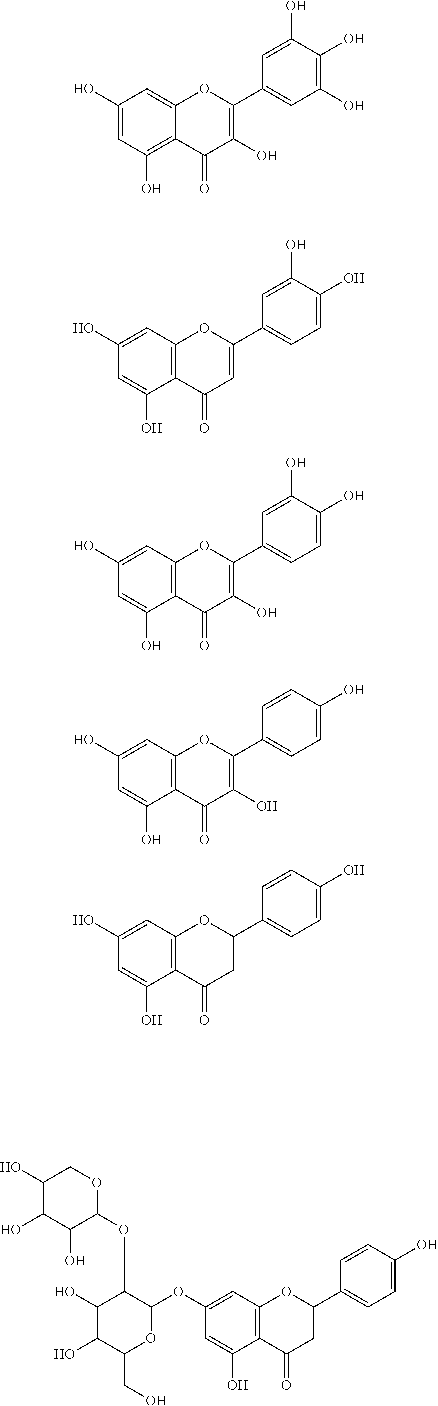 [SMILES: O=c1c(O)c(-c2cc(O)c(O)c(O)c2)oc2cc(O)cc(O)c12 ; O=c1cc(-c2ccc(O)c(O)c2)oc2cc(O)cc(O)c12 ; O=c1c(O)c(-c2ccc(O)c(O)c2)oc2cc(O)cc(O)c12 ; O=c1c(O)c(-c2ccc(O)cc2)oc2cc(O)cc(O)c12 ; O=C1CC(c2ccc(O)cc2)Oc2cc(O)cc(O)c21 ; O=C1CC(c2ccc(O)cc2)Oc2cc(OC3OC(CO)C(O)C(O)C3OC3OCC(O)C(O)C3O)cc(O)c21]

In yet other example embodiments, the radical quencher may include at least one selected from flavonoid compounds, such as 4′-hydroxyacetophenone protocatechuic acid, syringic acid, patuletin, quercetagetin 7-O-β-D-glucoside, patuletin 7-O-β-D-glucoside, and axillarin 7-O-β-D-glucoside. However, the inventive concept is not limited thereto.

In the photoresist composition according to some embodiments, the radical quencher may be used alone or in combination of at least two kinds thereof. The radical quencher may be contained at a content of about 0.1% to about 30% by weight, based on the total weight of the metal structure. When a content of the radical quencher in the photoresist composition is excessively low or high, a difference in solubility in the developer between an exposed area and a non-exposed area of the photoresist film may not be sufficiently increased.

In the photoresist composition according to some embodiments, when the photobase generator absorbs active energy rays by light irradiation, a base may be generated by decomposing a chemical structure of the photobase generator. In example embodiments, the photobase generator may include a material capable of generating a base having a pKa of at least 10 in water, but the inventive concept is not limited thereto.

A material included in the photobase generator is not specifically limited and may be any material capable of generating a base by light irradiation. In example embodiments, the photobase generator may include a nonionic photobase generator. In other example embodiments, the photobase generator may include an ionic photobase generator. Due to an acid-base reaction of the base generated from the photobase generator by light irradiation with the radical quencher in the exposed area of the photoresist film obtained from the photoresist composition according to some embodiments, the radical quencher may remain deprotonated and be deactivated.

In example embodiments, the photobase generator may include a carbamate compound, an α-aminoketone compound, a quaternary ammonium compound, an aminocyclopropenone compound, an O-acyloxime compound, or a 2-(9-oxoxanthen-2-yl) propionic acid 1,5,7-triazabicyclo[4.4.0]dec-5-ene salt.

Examples of the photobase generator including the carbamate compound may include 1-(2-anthraquinonyl)ethyl 1-piperidinecarboxylate, 1-(2-anthraquinonyl)ethyl 1H-2-ethylimidazole-1-carboxylate, 9-anthrylmethyl N,N-diethylcarbamate, 9-anthrylmethyl 1H-imidazole-1-carboxylate, bis[1-(2-anthraquinonyl)ethyl] 1,6-hexanediylbiscarbamate, and bis(9-anthrylmethyl) 1,6-hexanediylbiscarbamate.

Examples of the photobase generator including the α-aminoketone compound may include 1-phenyl-2-(4-morpholinobenzoyl)-2-dimethylaminobutane and 2-(4-methylthiobenzoyl)-2-morpholinopropane.

Examples of the photobase generator including the quaternary ammonium compound may include 1-(4-phenylthiophenacyl)-(1-azonia-4-azabicyclo[2.2.2]octane) tetraphenylborate, 5-(4-phenylthiophenacyl)-1-aza-5-azoniabicyclo[4,3,0]-5-nonene tetraphenylborate, and 8-(4-phenylthiophenacyl)-1-aza-8-azoniabicyclo[5,4,0]-7-undecene tetraphenylborate.

Examples of the photobase generator including the aminocyclopropenone compound may include 2-diethylamino-3-phenylcyclopropenone, 2-diethylamino-3-(1-naphthyl)cyclopropenone, 2-pyrrolidinyl-3-phenylcyclopropenone, 2-imidazolyl-3-phenylcyclopropenone, and 2-isopropylamino-3-phenylcyclopropenone.

The photobase generator including the O-acyloxime compound may be represented by General formula 2.

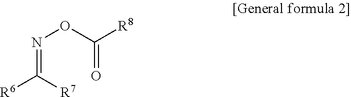

wherein each of R⁶, R⁷, and R⁸ may be independently a hydrogen atom, a C1 to C10 alkyl group, a C6 to C10 aryl group, or a C7 to C10 arylalkyl group.

In example embodiments, by light irradiation, the photobase generator may generate bicyclic amidines, for example, amidines such as 1,8-diazabicyclo[5.4.0]undec-7-ene (DBU) and 1,5-diazabicyclo[4.3.0]non-5-ene (DBN), or guanidine-type amines. The DBU may be a material having a pKa of about 13.5 in water and effectively deactivate an acidic radical quencher including a phenolic compound.

In example embodiments, the photobase generator may include ammonium salts.

In example embodiments, the photobase generator may include at least one selected from the following compounds. However, the inventive concept is not limited thereto.

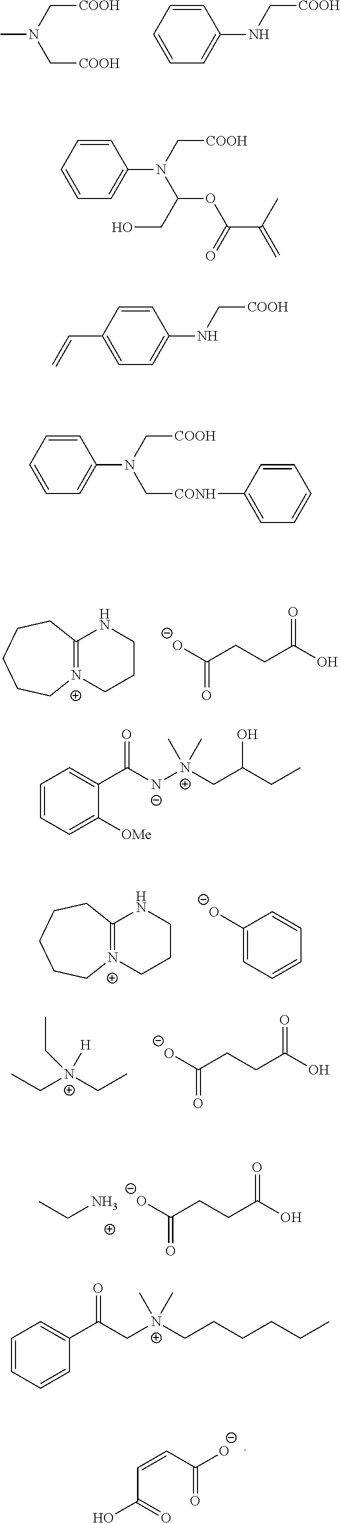

In other example embodiments, the photobase generator may include at least one ammonio group selected from the following ammonio groups. However, the inventive concept is not limited thereto.

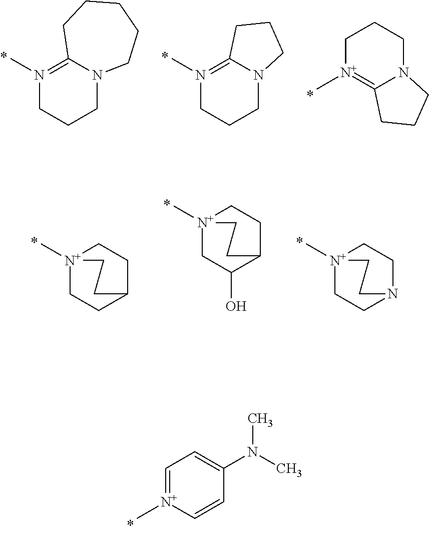

In Formulas presented above, “*” denotes a bonding site.

For example, the photobase generator may include at least one ammonium salt selected from Formula 8 to Formula 11. However, the inventive concept is not limited thereto.

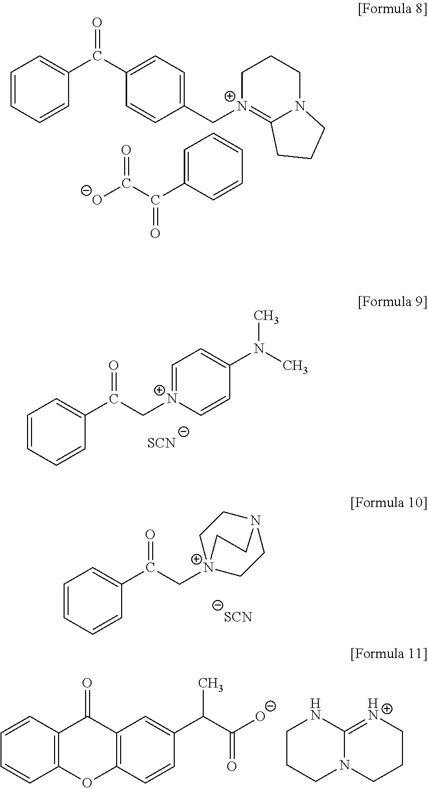

The compound of Formula 8 may generate 1,8-diazabicyclo[5.4.0]undec-7-ene (DBU) by light irradiation. The compound of Formula 11 may generate 1,5,7-triazabicyclo[4.4.0]dec-5-ene (TBD) by light irradiation.

In other example embodiments, the photobase generator may include at least one compound selected from Formulas 12 and 13. However, the inventive concept is not limited thereto.

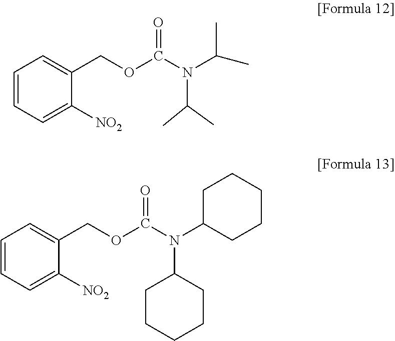 [SMILES: CC(C)N(C(=O)OCc1ccccc1[N+](=O)[O-])C(C)C ; O=C(OCc1ccccc1[N+](=O)[O-])N(C1CCCCC1)C1CCCCC1]

In yet other example embodiments, the photobase generator may be one selected from 5-benzyl-1,5-diazabicyclo[4.3.0]nonane, 5-(anthracen-9-yl-methyl)-1,5-diaza[4.3.0]nonane, 5-(2′-nitrobenzyl)-1,5-diazabicyclo[4.3.0]nonane, 5-(4′-cyanobenzyl)-1,5-diazabicyclo[4.3.0]nonane, 5-(3′-cyanobenzyl)-1,5-diazabicyclo[4.3.0]nonane, 5-(anthraquinon-2-yl-methyl)-1,5-diaza[4.3.0]nonane, 5-(2′-chlorobenzyl)-1,5-diazabicyclo[4.3.0]nonane, 5-(4′-methylbenzyl)-1,5-diazabicyclo[4.3.0]nonane, 5-(2′,4′,6′-trimethylbenzyl)-1,5-diazabicyclo[4.3.0]nonane, 5-(4′-ethenylbenzyl)-1,5-diazabicyclo[4.3.0]nonane, 5-(3′-trimethylbenzyl)-1,5-diazabicyclo[4.3.0]nonane, 5-(2′,3′-dichlorobenzyl)-1,5-diazabicyclo[4.3 O]nonane, 5-(naphth-2-yl-methyl-1,5-diazabicyclo[4.3.0]nonane, 1,4-bis(1,5-diazabicyclo[4.3.0]nonanylmethyl)benzene, 8-benzyl-1,8-diazabicyclo[5.4.0]undecane, 8-benzyl-6-methyl-1,8-diazabicyclo[5.4.0]undecane, 9-benzyl-1,9-diazabicyclo[6.4.0]dodecane, 10-benzyl-8-methyl-10-diazabicyclo[7.4.0]tridecane, 11-benzyl-1,11-diazabicyclo[8.4.0]tetradecane, 8-(2′-chlorobenzyl)-1,8-diazabicyclo[5.4.0]undecane, 8-(2′,6′-dichlorobenzyl)-1,8-diazabicyclo[5.4.0]undecane, 4-(diazabicyclo[4.3.0]nonanylmethyl)-1,1′-biphenyl, 4,4′-bis(diazabicyclo[4.3.0]nonanylmethyl)-11′-biphenyl, 5-benzyl-2-methyl-1,5-diazabicyclo[4.3.0]nonane, 5-benzyl-7-methyl-1,5,7-triazabicyclo[4.4.0]decane, and a combination thereof.

In the photoresist composition according to some embodiments, the photobase generator may be used alone or in combination of at least two kinds thereof. The photobase generator may be contained at a content of about 0.1% to about 30% by weight, based on the total weight of the metal structure. When a content of the photobase generator in the photoresist composition is excessively low, the ability to deactivate the radical quencher in the exposed area of the photoresist film obtained from the photoresist composition according to some embodiments may be reduced, and the difference in solubility in the developer between the exposed area and the non-exposed area of the photoresist film may not be sufficiently increased When the content of the photobase generator in the photoresist composition is excessively high, the ability to form the photoresist film using the photoresist composition may be reduced.

The solvent included in the photoresist composition may include an organic solvent. The organic solvent may include at least one of ether, alcohol, glycolether, aromatic hydrocarbon compound, ketone, and ester, without being limited thereto. For example, the organic solvent may include ethylene glycol monomethylether, ethylene glycol monoethylether, methylcellosolve acetate, ethylcellosolve acetate, diethylene glycolmethylether, diethylene glycolethylether, propylene glycol, propylene glycolmethylether (PGME), propylene glycolmethylether acetate (PGMEA), propylene glycolethylether, propylene glycolethylether acetate, propylene glycolpropylether acetate, propylene glycolbutylether, propylene glycolbutylether acetate, ethanol, propanol, isopropyl alcohol, isobutyl alcohol, 4-methyl-2-pentanol (or methyl isobutyl carbinol (MIBC)), hexanol, 1-methoxy-2-propanol, 1-ethoxy-2-propanol, ethylene glycol, propylene glycol, heptanone, propylene carbonate, butylene carbonate, toluene, xylene, methylethylketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or a combination thereof.

In the photoresist composition according to some embodiments, the solvent may be contained at a content of the remaining percentage excluding the contents of main components including the metal structure, the radical quencher, and the photobase generator. In example embodiments, the solvent may be contained at a content of about 0.1% to about 99.7% by weight, based on the total weight of the photoresist composition.

In example embodiments, the photoresist composition according to some embodiments may further include at least one selected from a surfactant, a dispersant, a desiccant, and a coupling agent.

The surfactant may improve the coating uniformity and wettability of the photoresist composition. In example embodiments, the surfactant may include sulfuric acid ester salts, sulfonates, phosphate ester, soap, amine salts, quaternary ammonium salts, polyethylene glycol, alkylphenol ethylene oxide adducts, polyhydric alcohol, a nitrogen-containing vinyl polymer, or a combination thereof, without being limited thereto. For example, the surfactant may include alkylbenzene sulfonates, alkylpyridinium salts, polyethylene glycol, or quaternary ammonium salts. When the photoresist composition includes the surfactant, the surfactant may be contained at a content of about 0.001% to about 3% by weight, based on the total weight of the photoresist composition.

The dispersant may uniformly disperse respective components in the photoresist composition. In example embodiments, the dispersant may include an epoxy resin, polyvinyl alcohol, polyvinyl butyral, polyvinylpyrrolidone, glucose, sodium dodecyl sulfate, sodium citrate, oleic acid, linoleic acid, or a combination thereof, without being limited thereto. When the photoresist composition includes the dispersant, the dispersant may be contained at a content of about 0.001% to about 5% by weight, based on the total weight of the photoresist composition.

The desiccant may reduce or prevent adverse effects due to moisture in the photoresist composition. For example, the desiccant may reduce or prevent oxidation of a metal included in the photoresist composition due to moisture. In example embodiments, the desiccant may include polyoxyethylene nonylphenolether, polyethylene glycol, polypropylene glycol, polyacrylamide, or a combination thereof, without being limited thereto. When the photoresist composition includes the desiccant, the desiccant may be contained at a content of about 0.001% to about 10% by weight, based on the total weight of the photoresist composition.

The coupling agent may increase adhesion of the photoresist composition with a lower film when the lower film is coated with the photoresist composition. In example embodiments, the coupling agent may include a silane coupling agent. The silane coupling agent may include vinyl trimethoxysilane, vinyl triethoxysilane, vinyl trichlorosilane, vinyl tris((3-methoxyethoxy)silane, 3-methacryl oxypropyl trimethoxysilane, 3-acryl oxypropyl trimethoxysilane, p-styryl trimethoxysilane, 3-methacryl oxypropyl methyldimethoxysilane, 3-methacryl oxypropyl methyldiethoxysilane, or trimethoxy[3-(phenylamino)propyl]silane, without being limited thereto. When the photoresist composition includes the coupling agent, the coupling agent may be contained at a content of about 0.001% to about 5% by weight, based on the total weight of the photoresist composition.

In the photoresist composition according to some embodiments, when the solvent includes only the organic solvent, the photoresist composition may further include water. In this case, water may be contained at a content of about 0.001% to about 0.1% by weight, based on the total weight of the photoresist composition.

The photoresist composition according to some embodiments may not include and may be devoid of a photoacid generator (PAG) configured to generate acids in response to exposure to light.

As described above, the photoresist composition according to some embodiments may include the metal structure, the radical quencher including the phenolic compound, and the photobase generator. Accordingly, during a photolithography process using the photoresist composition according to some embodiments, even when radicals generated by exposure are diffused from the exposed area of the photoresist film obtained from the photoresist composition into the non-exposed area of the photoresist film, radicals diffused from the exposed area of the photoresist film may be quenched by the radical quencher in the non-exposed area of the photoresist film, while the radical quencher may be deactivated due to the base generated by the phobase generator due to exposure in the exposed area of the photoresist film. Accordingly, a network (hereinafter, referred to as a “metal network”) including a crosslinked structure (e.g., an M-M crosslinked structure) including a metal M or a crosslinked structure (e.g., an M-O-M crosslinked structure) including a crosslinking element or a functional group (e.g., an oxygen atom) and a plurality of metals M may be selectively densely formed from the metal structure in only the exposed area of the photoresist film, and a metal network may not be formed in the non-exposed area of the photoresist film. Accordingly, a difference in solubility in a developer between the exposed area and the non-exposed area of the photoresist film may be increased. Accordingly, when an IC device is manufactured using the photoresist composition according to some embodiments, an excellent resolution and improved sensitivity may be provided in a photolithography process, and the degradation of a critical dimension (CD) distribution of a pattern required for the IC device may be prevented during the formation of the pattern, thereby improving the dimensional accuracy of the pattern to be formed.

The photoresist composition according to the embodiment may be advantageously used to form a pattern having a relatively high aspect ratio. For example, the photoresist composition according to the embodiment may be advantageously used in a photolithography process for forming a pattern having a fine width, which is selected in the range of about 5 nm to about 100 nm.

Next, a method of manufacturing an IC device using the photoresist composition according to some embodiments will be described with reference to a specific example.

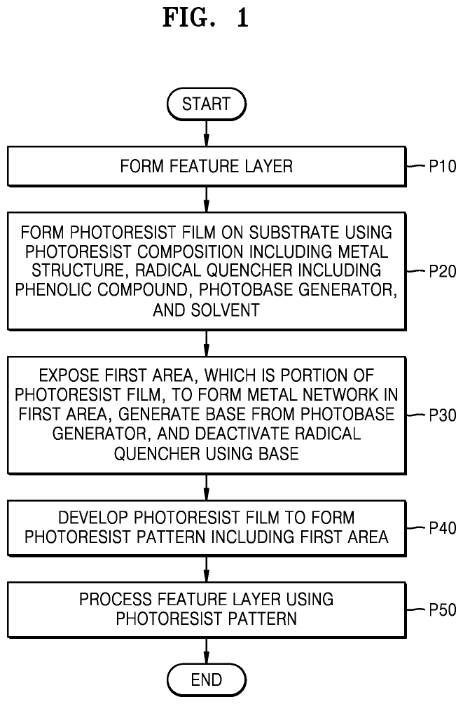

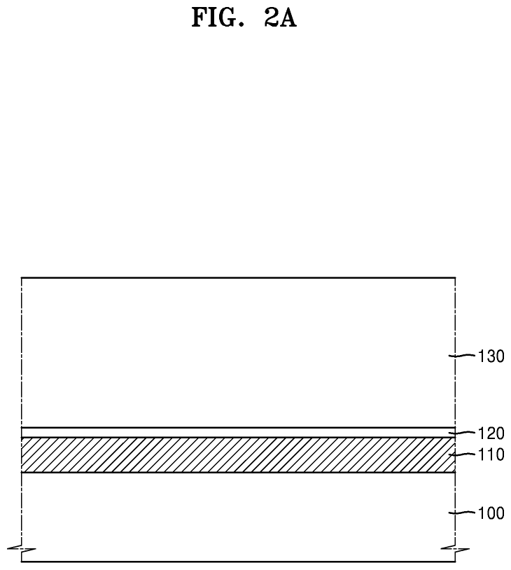

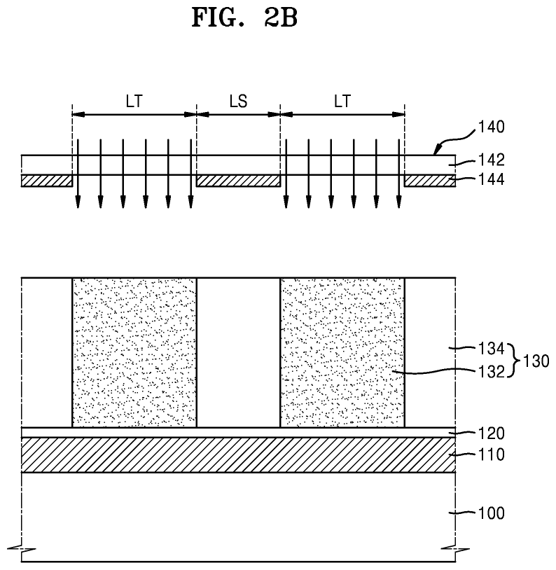

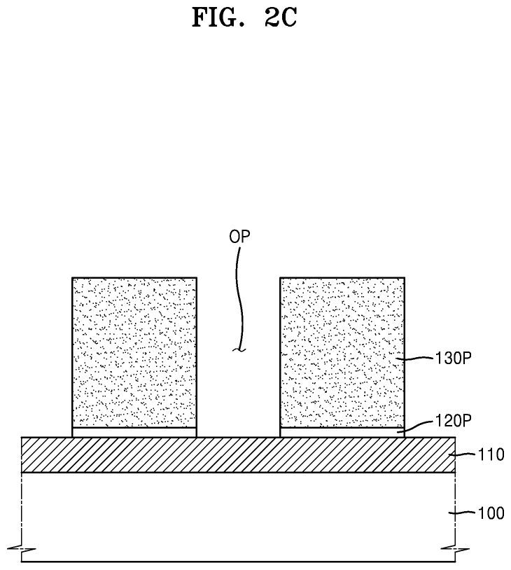

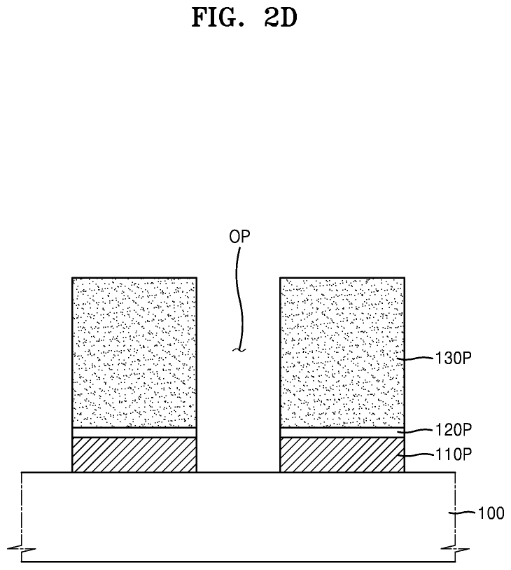

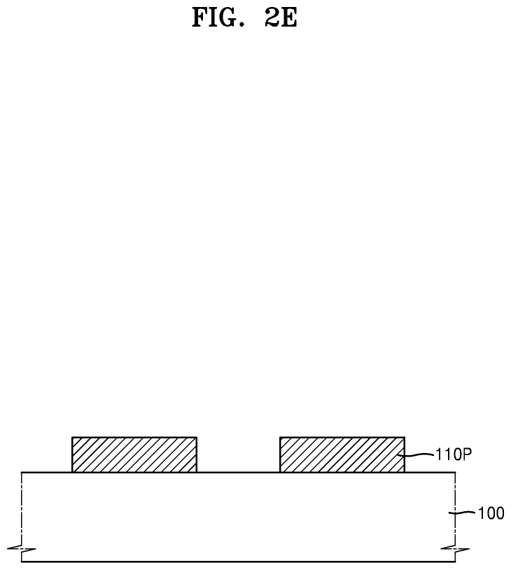

FIG. 1 is a flowchart of a method of manufacturing an IC device, according to some embodiments of the present inventive concept. FIGS. 2A to 2E are cross-sectional views illustrating methods of manufacturing an IC device, according to embodiments.

Referring to FIGS. 1 and 2A, a feature layer 110 may be formed on a substrate 100 in process P10, and a photoresist film 130 may be formed on the feature layer 110 using a photoresist composition according to some embodiments in process P20.

The photoresist film 130 may include a metal structure, which is a component of the photoresist composition, a radical quencher including a phenolic compound, a photobase generator, and a solvent. A detailed configuration of the photoresist composition is as described above.

The substrate 100 may include a semiconductor substrate. The feature layer 110 may include an insulating film, a conductive film, or a semiconductor film. For example, the feature layer 110 may include a metal, an alloy, a metal carbide, a metal nitride, a metal oxynitride, a metal oxycarbide, a semiconductor, polysilicon, oxide, nitride, oxynitride, or a combination thereof, without being limited thereto.

In example embodiments, as shown in FIG. 2A, before the photoresist film 130 is formed on the feature layer 110, a lower film 120 may be formed on the feature layer 110. In this case, the photoresist film 130 may be formed on the lower film 120. The lower film 120 may reduce or prevent adverse effects of the feature layer 110 to the photoresist film 130. In example embodiments, the lower film 120 may include an organic or inorganic anti-reflective coating (ARC) material for a krypton fluoride (KrF) excimer laser, an argon fluoride (ArF) excimer laser, an extreme ultraviolet (EUV) laser, or any other light source. In example embodiments, the lower film 120 may include a bottom anti-reflective coating (BARC) film or a developable bottom anti-reflective coating (DBARC) film. In other example embodiments, the lower film 120 may include an organic component having a light-absorbing structure. The light-absorbing structure may include, for example, at least one benzene ring or a hydrocarbon compound in which benzene rings are fused. The lower film 120 may be formed to a thickness of about 1 nm to about 100 nm, but the inventive concept is not limited thereto. In some embodiments, the lower film 120 may be omitted.

To form the photoresist film 130, a photoresist composition according to some embodiments may be coated on the lower film 120 and annealed. The coating process may be performed using a method, such as a spin coating process, a spray coating process, and a deep coating process. The process of annealing the photoresist composition may be performed at a temperature of about 80° C. to about 300° C. for about 10 seconds to about 100 seconds, without being limited thereto. A thickness of the photoresist film 130 may be several tens of times to several hundred times a thickness of the lower film 120. The photoresist film 130 may be formed to have a thickness of about 10 nm to about 1 μm, without being limited thereto.

Referring to FIGS. 1 and 2B, in process P30, a first area 132, which is a portion of the photoresist film 130, may be exposed to form a metal network in the first area 132, a base may be generated from the photobase generator in the first area 132, and the radical quencher may be deactivated using the base in the first area 132.

During the exposing of the photoresist film 130 in process P30 of FIG. 1, in the first area 132 of the photoresist film 130, which is exposed, organic ligands may be dissociated due to light absorption or secondary electrons generated by the light absorption in the metal structure included in the photoresist film 130 to form metal radicals, and a dense metal network may be formed due to a crosslinking reaction between the metal radicals. Accordingly, a difference in solubility in a developer between the first area 132 of the photoresist film 130, which is exposed, and a second area 134 of the photoresist film 130, which is not exposed, may be increased.

The base may be generated from the photobase generator in the first area 132 of the photoresist film 130, which is exposed. Accordingly, a deprotonation reaction may be caused by an acid-base reaction of the base generated from the photobase generator in the first area 132 with the radical quencher to remove hydrogen cations (W) of the radical quencher. As a result, hydrogen atoms may be separated from a hydroxyl functional group (—OH) included in the radical quencher. Accordingly, in the first area 132, the radical quencher may exist in an inactive state in which the radical quencher includes anionic oxygen atoms.

Because a base is not generated from the photobase generator in the second area 134 of the photoresist film 130, which is not exposed, a deprotonation reaction of the radical quencher may not occur in the second area 134 of the photoresist film 130. Thus, the radical quencher may remain in a state including the hydroxyl functional group (—OH) in the second area 134 of the photoresist film 130. Accordingly, in the second area 134 of the photoresist film 130, the radical quencher may exist in an active state in which the radical quencher may capture radicals.

Therefore, even when the metal radicals generated from the first area 132 of the photoresist film 130, which is exposed, are diffused into the second area 134 of the photoresist film 130, which is not exposed, the metal radicals diffused into the second area 134 of the photoresist film 130 may be captured by the radical quencher in the second area 134 of the photoresist film 130, thereby reducing or preventing the formation of metal-metal bonds. As a result, a metal network may be selectively formed in only the first area 132 of the photoresist film 130, which is exposed, and may not be formed in the second area 134 of the photoresist film 130, which is not exposed. Thus, a difference in solubility in the developer between the first area 132 and the second area 134 of the photoresist film 130 may be increased.

In example embodiments, to expose the first area 132 of the photoresist film 130, a photomask 140 having a plurality of light-shielding areas LS and a plurality of light-transmitting areas LT may be arranged at a predetermined position on the photoresist film 130, and the first area 132 of the photoresist film 130 may be exposed through the plurality of light-transmitting areas LT of the photomask 140. The first area 132 of the photoresist film 130 may be exposed using a KrF excimer laser (248 nm), an ArF excimer laser (193 nm), a fluorine (F₂) excimer laser (157 nm), or an EUV laser (13.5 nm).

The photomask 140 may include a transparent substrate 142 and a plurality of light-shielding patterns 144 formed on the transparent substrate 142 in the plurality of light-shielding areas LS. The transparent substrate 142 may include quartz. The plurality of light-shielding patterns 144 may include chromium (Cr). The plurality of light-transmitting areas LT may be defined by the plurality of light-shielding patterns 144. According to the inventive concept, a reflective photomask (not shown) for an EUV exposure process may be used instead of the photomask 140 to expose the first area 132 of the photoresist film 130.

In process P30 of FIG. 1, after the first area 132 of the photoresist film 130 is exposed, the photoresist film 130 may be annealed. The annealing process may be performed at a temperature of about 50° C. to about 400° C. for about 10 seconds to about 100 seconds, without being limited thereto. In example embodiments, the network of the metal structures in the first area 132 may be further densified during the annealing of the photoresist film 130. Thus, in the photoresist film 130, the difference in solubility in the developer between the first area 132, which is exposed, and the second area 134, which is not exposed, may be further increased. Accordingly, a high pattern fidelity may be obtained by reducing a Line Edge Roughness (LER) or aa Line Width Roughness (LWR) in a final pattern to be formed in the feature layer 110 during a subsequent process.

Referring to FIGS. 1 and 2C, in process P40, the photoresist film 130 may be developed using a developer to remove the second area 134 of the photoresist film 130. As a result, a photoresist pattern 130P including the first area 132 of the photoresist film 130, which is exposed, may be formed.

The photoresist pattern 130P may include a plurality of openings OP. After the photoresist pattern 130P is formed, portions of the lower film 120, which are exposed through the plurality of openings OP, may be removed to form a lower pattern 120P.

In example embodiments, the developing of the photoresist film 130 may be performed using a negative-tone development (NTD) process. In this case, normal-butyl acetate (or n-butyl acetate) or 2-heptanone may be used as the developer, but a kind of the developer is not limited thereto.

As described with reference to FIG. 2B, a difference in solubility in the developer between the first area 132 of the photoresist film 130, which is exposed, and the second area 134 of the photoresist film 130, which is not exposed, may be increased. Thus, the first area 132 may not be removed but remain as it is while the second area 134 is being removed by developing the photoresist film 130 during the process of FIG. 2C. Accordingly, after the photoresist film 130 is developed, residue defects, such as a footing phenomenon, may not occur, and the photoresist pattern 130P may obtain a vertical sidewall profile. As described above, by improving a profile of the photoresist pattern 130P, when the feature layer 110 is processed using the photoresist pattern 130P, a CD of an intended processing region may be precisely controlled in the feature layer 110.

Referring to FIGS. 1 and 2D, in process P50, the feature layer 110 may be processed using the photoresist pattern 130P in the resultant structure of FIG. 2C.

To process the feature layer 110, various processes, such as a process of etching the feature layer 110 exposed by the openings OP of the photoresist pattern 130P, a process of implanting impurity ions into the feature layer 110, a process of forming an additional film on the feature layer 110 through the openings OP, and a process of modifying portions of the feature layer 110 through the openings OP, may be performed. FIG. 2D illustrates a process of forming a feature pattern 110P by etching the feature layer 110, which is exposed by the openings OP, as an example of processing the feature layer 110.

In other example embodiments, the process of forming the feature layer 110 may be omitted from the process described with reference to FIG. 2A. In this case, the substrate 100 may be processed using the photoresist pattern 130P instead of the process described with reference to the process P50 of FIG. 1 and FIG. 2D. For example, various processes, such as a process of etching a portion of the substrate 100 using the photoresist pattern 130P, a process of implanting impurity ions into a partial region of the substrate 100, a process of forming an additional film on the substrate 100 through the openings OP, and a process of modifying portions of the substrate 100 through the openings OP, may be performed.

Referring to FIG. 2E, the photoresist pattern 130P and the lower pattern 120P, which remain on the feature pattern 110P, may be removed from the resultant structure of FIG. 2D. The photoresist pattern 130P and the lower pattern 120P may be removed using an ashing process and a strip process.

In the method of manufacturing the IC device according to some embodiments described with reference to FIGS. 1 and 2A to 2E, a difference in acidity between the exposed area and the non-exposed area may be increased to increase solubility in the developer between the exposed area and the non-exposed area of the photoresist film 130 obtained using the photoresist composition according to some embodiments. Thus, an LER and an LWR may be reduced in the photoresist pattern 130P obtained from the photoresist film 130 to provide a high pattern fidelity. Accordingly, when a subsequent process is performed on the feature layer 110 and/or the substrate 100 using the photoresist pattern 130P, a dimensional precision may be improved by precisely controlling critical dimensions of processing regions or patterns to be formed on the feature layer 110 and/or the substrate 100. In addition, a CD distribution of patterns to be formed on the substrate 100 may be uniformly controlled, and the productivity of a process of manufacturing an IC device may be increased.

While the inventive concept has been particularly shown and described with reference to example embodiments thereof, it will be understood that various changes in form and details may be made therein without departing from the scope of the following claims.

1. A photoresist composition comprising:
a metal structure comprising an organic metal compound, an organic metal nanoparticle, or an organic metal cluster;
a radical quencher comprising a phenolic compound;
a photobase generator; and
a solvent.

2. The photoresist composition of claim 1, wherein the radical quencher comprises a material having an acid dissociation constant (pKa) of about 3 to about 13 in water.

3. The photoresist composition of claim 1, wherein the phenolic compound of the radical quencher has a symmetric steric hindrance.

4. The photoresist composition of claim 1, wherein the phenolic compound of the radical quencher has an asymmetric steric hindrance.

5. The photoresist composition of claim 1, wherein the radical quencher comprises a monophenol compound.

6. The photoresist composition of claim 1, wherein the radical quencher comprises a polyphenol compound.

7. The photoresist composition of claim 1, wherein the radical quencher comprises a flavonoid compound.

8. The photoresist composition of claim 1, wherein, in response to exposure to light, the photobase generator comprises a material configured to generate a base having an acid dissociation constant (pKa) of at least about 10 in water.

9. The photoresist composition of claim 1, wherein the photobase generator comprises a nonionic photobase generator.

10. The photoresist composition of claim 1, wherein the photobase generator comprises an ionic photobase generator.

11. The photoresist composition of claim 1, wherein the photobase generator comprises at least one salt or compound selected from:

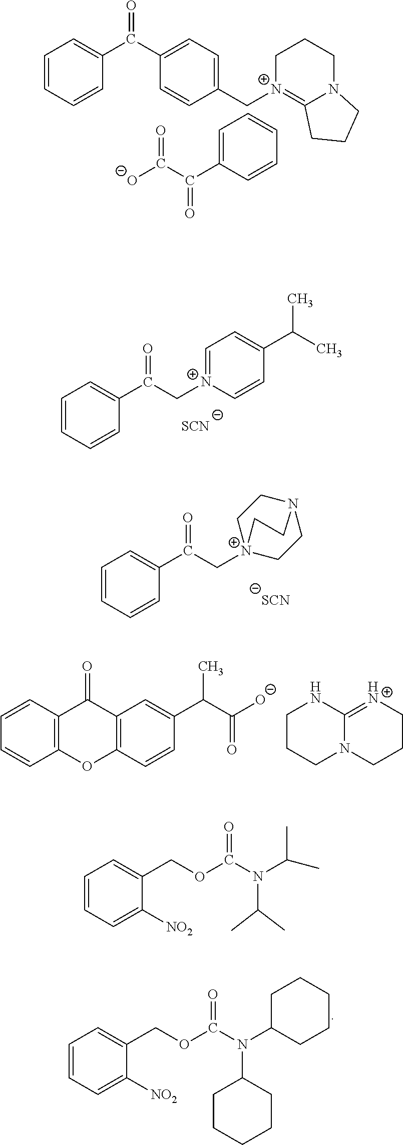

12. The photoresist composition of claim 1, wherein the metal structure comprises a metal core comprising at least one metal atom and at least one organic ligand associated with the metal core.

13. The photoresist composition of claim 1, wherein the metal structure comprises a metal selected from tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (V), chromium (Cr), cobalt (Co), nickel (Ni), copper (Cu), gallium (Ga), manganese (Mn), copper (Cu), strontium (Sr), tungsten (W), cadmium (Cd), molybdenum (Mo), tantalum (Ta), niobium (Nb), cesium (Cs), barium (Ba), lanthanum (La), cerium (Ce), iron (Fe), and any combination thereof.

14. The photoresist composition of claim 1, wherein the photoresist composition is devoid of a photoacid generator (PAG).

15. A photoresist composition comprising:
a metal structure comprising (i) a metal core comprising at least one metal atom and (ii) at least one organic ligand associated with the metal core;
a radical quencher comprising a phenolic compound;
a photobase generator comprising a material capable of generating a base having an acid dissociation constant (pKa) of at least about 10 in water; and
a solvent.

16. The photoresist composition of claim 15, wherein the radical quencher comprises a monophenol compound.

17. The photoresist composition of claim 15, wherein the radical quencher comprises a polyphenol compound.

18-20. (canceled)

21. A photoresist composition comprising:
a metal structure comprising a metal atom and an organic ligand bound to the metal atom;
a radical quencher comprising a phenolic compound; and
a photobase generator.

22. The photoresist composition of claim 21, wherein the phenolic compound is one of the following structures: 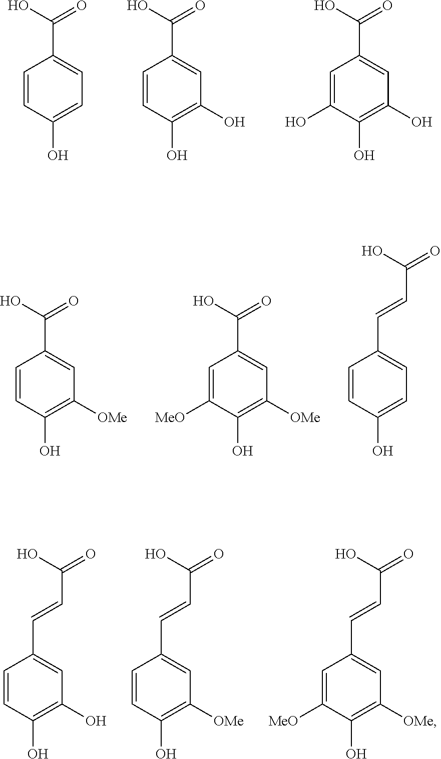
wherein Me is a methyl group.

23. The photoresist composition of claim 21, wherein the phenolic compound is one of the following structures: 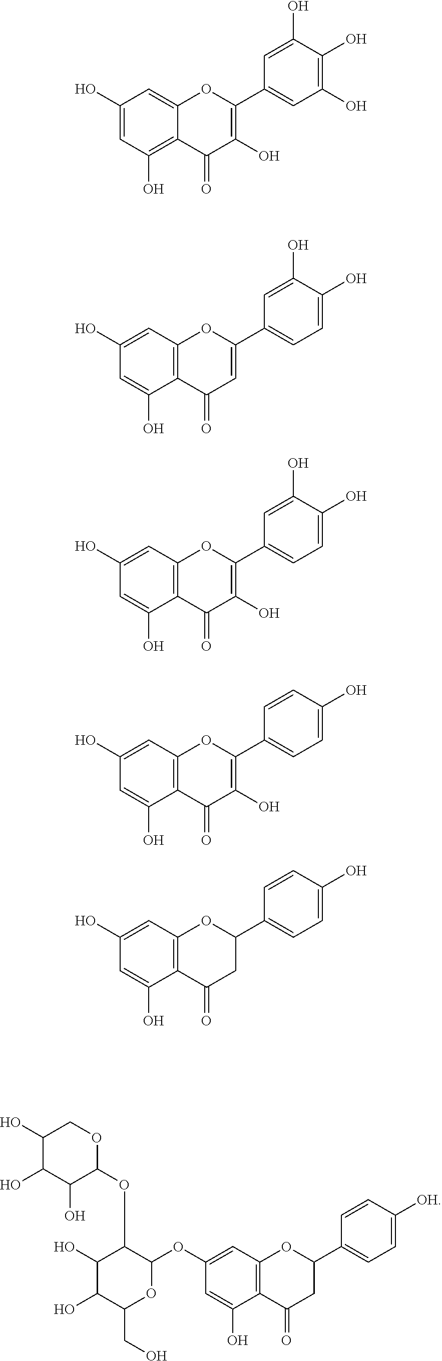 [SMILES: O=c1c(O)c(-c2cc(O)c(O)c(O)c2)oc2cc(O)cc(O)c12 ; O=c1cc(-c2ccc(O)c(O)c2)oc2cc(O)cc(O)c12 ; O=c1c(O)c(-c2ccc(O)c(O)c2)oc2cc(O)cc(O)c12 ; O=c1c(O)c(-c2ccc(O)cc2)oc2cc(O)cc(O)c12 ; O=C1CC(c2ccc(O)cc2)Oc2cc(O)cc(O)c21 ; O=C1CC(c2ccc(O)cc2)Oc2cc(OC3OC(CO)C(O)C(O)C3OC3OCC(O)C(O)C3O)cc(O)c21]
